(19) United States
(12) Patent Application Publication
(10) Pub. No.: US 2019/0031440 A1
(43) Pub. Date: Jan. 31, 2019

(54) STORAGE APPARATUS AND CONVEYANCE SYSTEM

(71) Applicant: MURATA MACHINERY, LTD., Kyoto-shi, Kyoto (JP)

(72) Inventor: Yasuhisa ITO, Ise-shi (JP)

(21) Appl. No.: 16/072,519

(22) PCT Filed: Dec. 28, 2016
(86) PCT No.: PCT/JP2016/089084

§ 371 Date: Jul. 25, 2018

(30) Foreign Application Priority Data
Feb. 15, 2016 (JP) 2016-025471

(51) Int. Cl. B65G 1/04; H01L 21/677

(52) U.S. Cl. CPC B65G 1/0407; B65G 2201/0297; B65G 1/0464; H01L 21/67769

(57) ABSTRACT

A storage apparatus includes a pair of storage portions including shelves on which a FOUP of a front-to-rear width narrower than a right-to-left width is to be placed, the storage portions being arranged facing each other in a front-and-rear direction, and a conveyor between the storage portions to transfer the FOUP between the shelves of the storage portions. In each storage portion, the shelves located at an identical height position are arrayed in a left-and-right direction. The conveyor places the FOUP, on each of the shelves, in a state in which a front surface of the FOUP faces the left-and-right direction.

### BACKGROUND OF THE INVENTION

### 1. Field of the Invention

The present disclosure relates to a storage apparatus that stores containers, and a conveyance system.

### 2. Description of the Related Art

Conventionally, semiconductor conveyance systems are provided with a storage apparatus (stocker) for temporarily storing containers that accommodate semiconductor wafers of a front-to-rear width narrower than a right-to-left width (front opening unified pod (FOUP)) or the like. As for the storage apparatus, a known structure includes a pair of front and rear storage portions each having a plurality of shelves arrayed from side to side and up and down (see Japanese Unexamined Patent Publication No. 2003-171003).

The above-described storage apparatus is generally assembled at a delivery destination (a semiconductor manufacturing plant or the like in which the storage apparatus is used). However, when the assembly work is conducted at the delivery destination, the work cost tends to become higher than when conducting the assembly work at a consigner (a manufacturing plant or the like of the storage apparatus). Thus, it is desired that the storage apparatus assembled at the consigner can be carried into the delivery destination as is or in as few assembling units as possible. However, in order to make it possible to ship the storage apparatus that has been assembled at the consigner, it is necessary to downsize the storage apparatus.

### SUMMARY OF THE INVENTION

Thus, preferred embodiments of the present invention provide storage apparatuses that are downsized by increasing the storage density of containers, and conveyance systems that include the storage apparatuses.

A storage apparatus according to a preferred embodiment of the present invention includes a pair of storage portions including a plurality of shelves on which a container of a front-to-rear width narrower than a right-to-left width is to be placed, the storage portions facing each other in a first direction; and a conveyor provided between the pair of storage portions to transfer the container between the shelves of the pair of storage portions and, in each of the pair of storage portions, the plurality of shelves that are located at an identical height position are arrayed in a second direction orthogonal to the first direction, and the conveyor places the container on each of the plurality of shelves in a state in which a front surface of the container faces the second direction.

In each of the pair of storage portions, the container is placed such that the front surface of the container faces the array direction of the shelves (the second direction, that is, the longitudinal direction of the storage portion). The front-to-rear width of the container is narrower than the right-to-left width of the container. Thus, according to the above-described storage apparatus, the storage density of the containers in the longitudinal direction of the respective storage portions is increased as compared with the configuration in which the containers are placed on the shelves such that the side surface of the container faces the array direction of the shelves. As a result, it is possible to downsize the storage apparatus by shortening the total length in the longitudinal direction of the storage apparatus.

In the above-described storage apparatus, the conveyor may horizontally swivel the container received from the shelf of one storage portion of the pair of storage portions by 180 degrees and hand it over to the shelf of the other storage portion of the pair of storage portions. According to this structure, because the interval between the containers placed on the shelves adjacent in the up-and-down direction is able to be made relatively small, it is possible to increase the storage density of the containers in the height direction of the respective storage portions. As a result, it is possible to downsize the storage apparatus by shortening the total length in the height direction of the storage apparatus.

In the above-described storage apparatus, each of the pair of storage portions may include a port that is able to be accessed by an overhead carrier to convey the container along the first direction, and the port of one of the storage portions may include a swivel to horizontally swivel the container placed on the port by 180 degrees. When the conveyor horizontally swivels the container by 180 degrees and transfers the container from the shelf of one storage portion to the shelf of the other storage portion, the direction of the container placed on the shelf of the one storage portion and the direction of the container placed on the shelf of the other storage portion are opposite to each other. Meanwhile, the direction of the container for which the overhead carrier is capable of conveying (the direction of the container with respect to the traveling direction of the overhead carrier) is predetermined. According to the above-described configuration, by the simple configuration in which the swivel is provided on the port of one of the storage portions, the directions of the containers placed on the respective ports of the storage portions (that is, the direction of the container immediately after incoming and the direction of the container immediately before outgoing) are able to be made coincident with the direction for which the overhead carrier is capable of conveying. As a result, the overhead carrier that travels along the first direction is able to use any of the ports of the storage portions for incoming or outgoing. Accordingly, it is possible to improve the efficiency of the incoming-and-outgoing operations of the containers by the overhead carrier.

In the above-described storage apparatus, the port of one storage portion of the pair of storage portions may be a port for incoming, and the port of the other storage portion of the pair of storage portions may be a port for outgoing. According to this configuration, the pair of storage portions are able to be divided into a storage portion exclusively for incoming and a storage portion exclusively for outgoing. As a result, it is possible to smoothly perform incoming and outgoing operations to and from the container by the overhead carrier and is possible to significantly reduce or prevent the occurrence of the congestion of the overhead carrier.

In the above-described storage apparatus, at least one of the storage portions of the pair of storage portions may include a first port at which incoming or outgoing of the container is performed by an overhead carrier that conveys the container moving the container in an up-and-down direction at a certain stop position, and a second port at which incoming or outgoing of the container is performed by the overhead carrier moving the container in a horizontal direction and the up-and-down direction at the certain stop position. According to this configuration, it is possible to perform incoming-and-outgoing operations (that is, accessing the first port and the second port) by the overhead carrier stopped at the certain position as a series of transfer operations. For example, the overhead carrier is able to, after depositing a container at one of the first port and the second port, carry a container from the other of the first port and the second port. As a result, it is possible to smoothly perform the inserting and extracting of the container by the overhead carrier and is possible to significantly reduce or prevent the occurrence of the congestion of the overhead carrier.

A conveyance system according to a preferred embodiment of the present invention includes the above-described storage apparatus, and an overhead carrier that is able to access at least one storage portion of the pair of storage portions and to convey the container along the first direction in a state in which the front surface of the container faces the second direction. In the above-described conveyance system, for the above-described reasons, it is possible to downsize the storage apparatus by shortening the total length in the longitudinal direction of the storage apparatus. In addition, in the above-described conveyance system, the container that is conveyed by the overhead carrier, and the containers that are placed on the storage portions are all in a state in which the front surface of the container faces the second direction. Accordingly, there is no need to have a mechanism or the like that is needed when the traveling direction of the overhead carrier and the direction of the pair of storage portions facing each other are orthogonal (for example, a mechanism that horizontally swivels the container placed on the storage portion by 90 degrees). Thus, according to the conveyance system in which the storage apparatus and the overhead carrier are arranged as described above, it is possible to simplify the structure of the storage apparatus.

According to preferred embodiments of the present invention, it is possible to provide storage apparatuses that are downsized by increasing the storage density of the containers, and to provide conveyance systems including the storage apparatuses.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a planar cross-sectional view of a storage apparatus according to a first preferred embodiment of the present invention.

FIG. 2 is a cross-sectional view taken along the line II-II in FIG. 1.

FIG. 3 is a partial cross-sectional view taken along the line III-III in FIG. 1.

FIG. 4 is a partial cross-sectional view taken along the line IV-IV in FIG. 1.

FIG. 5 is a side view of the storage apparatus in FIG. 1.

FIG. 6 is a partial cross-sectional view of a storage apparatus according to a second preferred embodiment of the present invention.

### DETAILED DESCRIPTION OF THE PREFERRED EMBODIMENTS

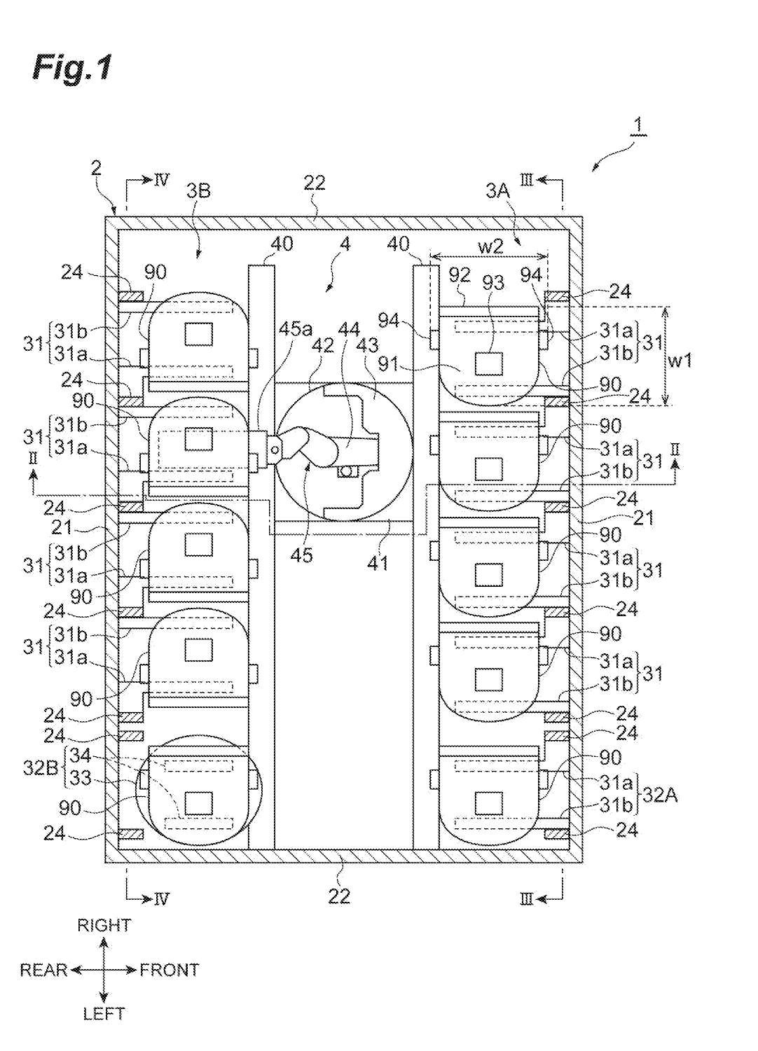

With reference to the accompanying drawings, the following describes exemplary preferred embodiments of the present disclosure in detail. In the description of the drawings, identical or equivalent elements are denoted by identical reference signs, and redundant explanations are omitted. In the following description, it is assumed that the right-hand direction on the plane of FIG. 1 is the front direction, the left-hand direction is the rear direction, the upward direction is the right-hand direction, and the downward direction is the left-hand direction. It is further assumed that the direction toward the near side of the plane of FIG. 1 is the up direction and the direction toward the back side of the plane is the down direction.

### First Preferred Embodiment

As illustrated in FIGS. 1 to 5, a storage apparatus 1 according to a first preferred embodiment of the present invention is capable of accommodating a plurality of FOUPs 90 as containers that accommodate a plurality of semiconductor wafers. The FOUP 90 is a carrier that is specified in the SEMI standard for the purpose of conveying and storing 300 mm semiconductor wafers that are used in a semiconductor manufacturing plant of a mini-environment system, for example. In the present preferred embodiment, as one example, the FOUP 90 includes a main body 91, a door 92, a flange 93, and a pair of handles 94 and 94. The main body 91 is a box-shaped housing that accommodates semiconductor wafers. On the front side of the main body 91, an opening for taking a semiconductor wafer in and out is provided, and the rear side of the main body 91 has a rounded curved shape in planar view (see FIG. 1). The door 92 closes the opening of the main body 91 and is detachable with respect to the main body 91. The flange 93 is provided on the upper surface of the main body 91. The flange 93 is grasped by a gripper 11 of an overhead carrier 10 which will be described later. The handles 94 and 94 are provided on both side surfaces of the main body 91. A worker can easily carry the FOUP 90, for example, by holding the FOUP 90 from the rear side of the main body 91 and by gripping the handles 94 with both hands and hoisting the FOUP 90. A front-to-rear width w1 of the FOUP 90 is narrower than a right-to-left width w2 of the FOUP 90.

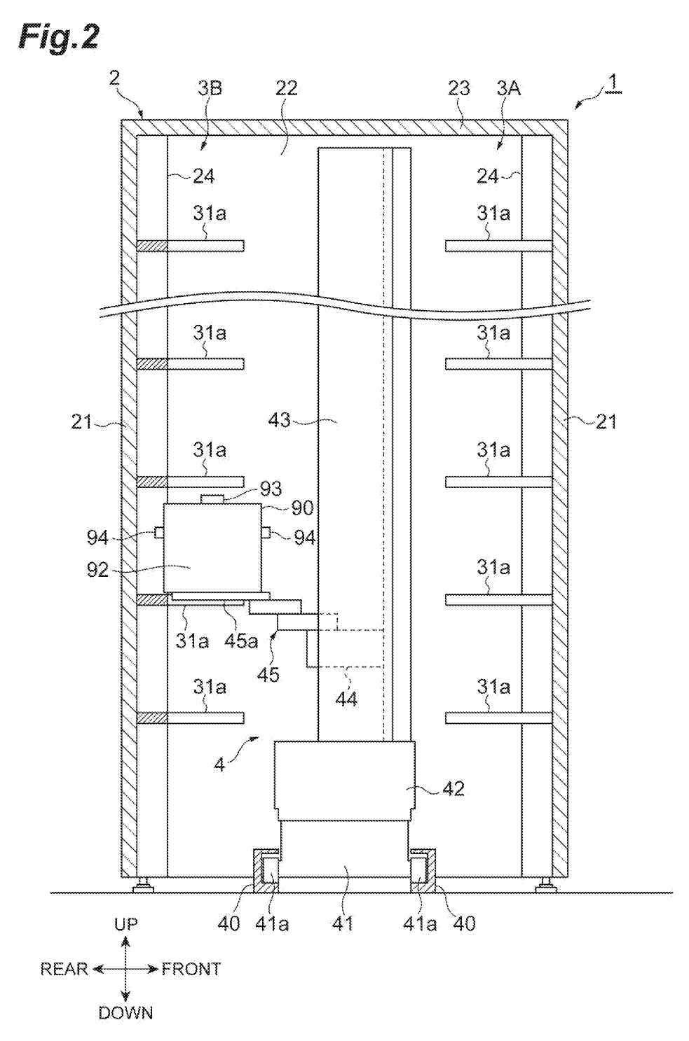

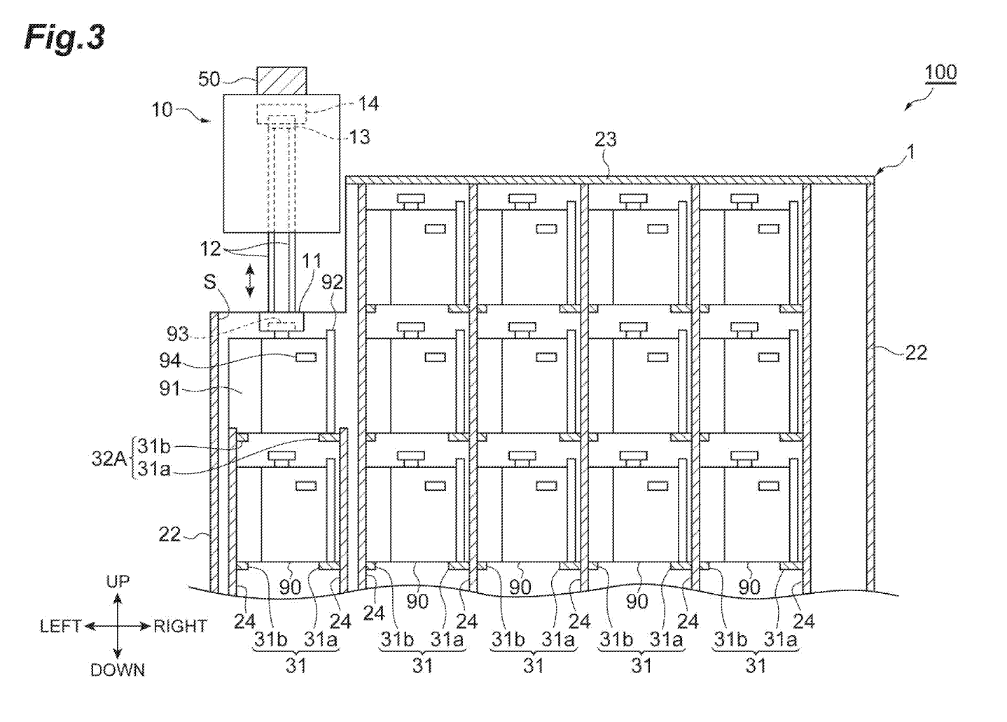

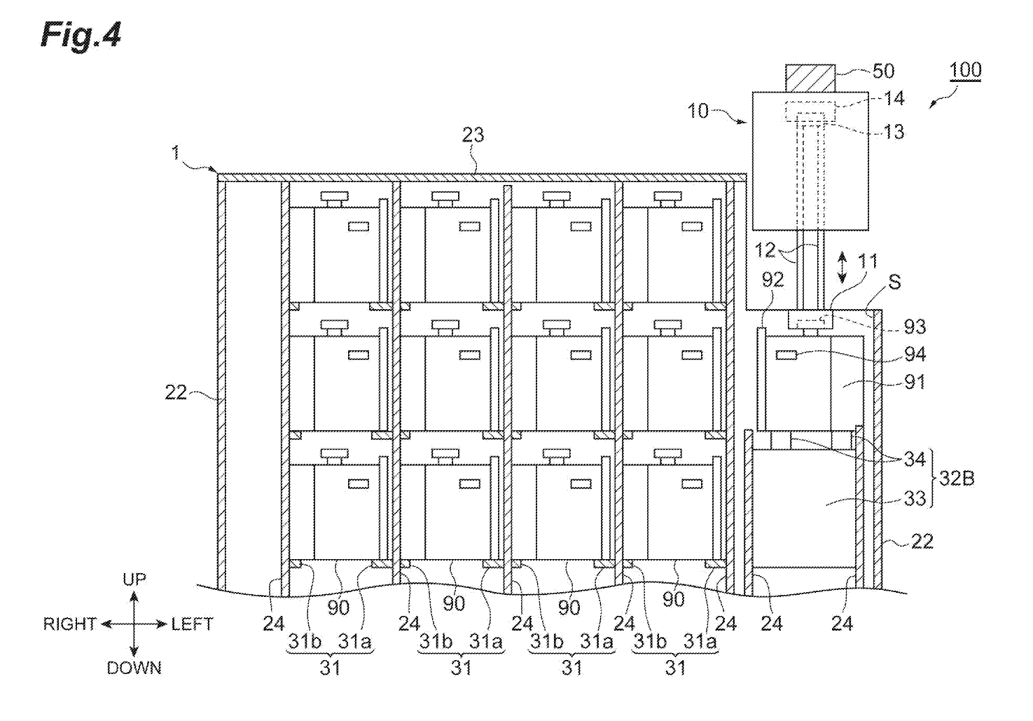

The storage apparatus 1 includes, in a rectangular or substantially rectangular parallelepiped housing 2, a pair of storage portions 3A and 3B, and a conveyor 4 that is provided between the storage portion 3A and the storage portion 3B. As illustrated in FIGS. 1 and 2, the housing 2 includes sidewalls 21 and 21 that face each other in the front-and-rear direction (first direction), sidewalls 22 and 22 that face each other in the left-and-right direction (second direction), and a top plate 23 that covers the upper surface of the sidewalls 21 and 21 and the sidewalls 22 and 22. In addition, support posts 24 are provided upright at certain intervals in the left-and-right direction along the sidewall 21. The housing 2 preferably has a rectangular or substantially rectangular parallelepiped shape by the sidewall 21 and 21, the sidewall 22 and 22, and the top plate 23. The housing 2 has a shape in which ports 32A and 32B, which will be described later, are opened to the outside, such that it is possible to transfer the FOUP 90 between the overhead carrier 10 and the ports 32A and 32B (see FIGS. 3 and 4). In the present preferred embodiment, as one example, the housing 2 is provided with an opening S that opens at least an upper side of the ports 32A and 32B such that the overhead carrier 10 is able to access the ports 32A and 32B from above.

As illustrated in FIGS. 1 and 2, the storage portions 3A and 3B face each other in the front-and-rear direction along the respective sidewall 21 and 21. The storage portion 3A extends along the sidewall 21 of the front side, and the storage portion 3B extends along the sidewall portion 21 of the rear side. Each of the storage portions 3A and 3B includes a plurality of shelves on which the FOUP 90 is placed. In the respective storage portions 3A and 3B, the plurality of shelves 31 are arrayed in the up-and-down direction and the left-and-right direction. That is, the plurality of shelves 31 are provided in multiple stages in the up-and-down direction. In addition, the plurality of shelves 31 located at an identical height position are arrayed in juxtaposition in the left-and-right direction.

On each shelf 31, the FOUP 90 is placed in a state in which the front surface (that is, the surface on the side on which the door 92 is provided with respect to the main body 91) of the FOUP 90 faces the left-and-right direction. As illustrated in FIG. 1, in the present preferred embodiment, as one example, on the shelves 31 of the storage portion 3A, the FOUPs 90 are placed in a state in which the front surface of the FOUP 90 faces the right-hand direction. On the shelves 31 of the storage portion 3B, the FOUPs 90 are placed in a state in which the front surface of the FOUP 90 faces the left-hand direction. As in the foregoing, the front-to-rear width w1 of the FOUP 90 is narrower than the right-to-left width w2 of the FOUP 90. Accordingly, by placing the FOUPs 90 on the shelves 31 as in the foregoing, it is possible to increase the storage density of the FOUPs 90 in the left-and-right direction of the respective storage portions 3A and 3B as compared with a case in which the FOUPs 90 are placed on the shelves 31 such that the side surface of the FOUP 90 faces the array direction (that is, the left-and-right direction) of the shelves 31. As a result, it is possible to downsize the storage apparatus 1 by shortening the total length in the left-and-right direction of the storage apparatus 1.

In the present preferred embodiment, as one example, each shelf 31 includes a first shelf member 31a that supports a portion on the front side of the bottom surface of the FOUP 90, and a second shelf member 31b that supports a portion on the rear side of the bottom surface of the FOUP 90. The first shelf member 31a and the second shelf member 31b are each attached to the support posts 24.

Specifically, as illustrated in FIG. 1, the first shelf member 31a and the second shelf member 31b of the shelf 31 of the storage portion 3A are attached to the left-side surface and the right-side surface of the support posts 24, respectively. That is, a single shelf 31 of the storage portion 3A includes a combination of the first shelf member 31a that is attached to one support post 24 and the second shelf member 31b that is attached to the support post 24 located on the left-hand side of the one support post 24. Meanwhile, the first shelf member 31a and the second shelf member 31b of the shelf 31 of the storage portion 3B are attached to the right-side surface and the left-side surface of the support posts 24, respectively. A single shelf 31 of the storage portion 3B includes a combination of the first shelf member 31a that is attached to one support post 24 and the second shelf member 31b that is attached to the support post 24 located on the right-hand side of the one support post 24. Between the first shelf member 31a and the second shelf member 31b defining a single shelf 31, a certain interval is provided so that a fork 45a of the conveyor 4 which will be described later is able to enter to perform the transfer (load-scooping or unloading) of the FOUP 90.

The conveyor 4 is able to transfer the FOUP 90 between the shelves 31 of the storage portions 3A and 3B. The conveyor 4 places the FOUP 90, by a mechanism which will be described in the following, on each of the plurality of shelves 31, in a state in which the front surface of the FOUP 90 faces the left-and-right direction. As illustrated in FIGS. 1 and 2, the conveyor 4 includes a pair of rails 40 and 40 that are laid along the left-and-right direction between the storage portions 3A and 3B, a dolly 41 that is movable in the left-and-right direction along the rails 40 and 40, a rotary table 42 provided on the dolly 41, a mast 43 erected on the rotary table 42, an elevating table 44 attached to the mast 43 so as to be movable up and down with respect to the mast 43, and a transporter 45 mounted on the elevating table 44. In FIG. 2, the depiction of the FOUPs 90 other than the FOUP 90 that is a subject of transfer is omitted.

The dolly 41 is provided with traveling wheels 41a and 41a. The traveling wheels 41a and 41a are supported on the rails 40 and 40 to enable the dolly 41 to travel along the rails 40 and 40. The conveyor 4 is able to determine the position of the transporter 45 in the left-and-right direction, by making the dolly 41 travel with a driver that is not depicted. Specifically, the conveyor 4 is able to, by the traveling control of the dolly 41, make the transporter 45 move to the position in the left-and-right direction corresponding to the shelf 31 that is a subject of transfer of the FOUP 90.

The conveyor 4 is able to determine the position of the transporter 45 in the up-and-down direction, by raising and lowering the elevating table 44 in the up-and-down direction with a driver that is not depicted. Specifically, the conveyor 4 is able to move the transporter 45 to the position in the up-and-down direction corresponding to the shelf 31 that is a subject of transfer of the FOUP 90 by the elevating control of the elevating table 44.

The conveyor 4 is able to, by rotating the rotary table 42 with a driver that is not depicted, horizontally rotate the mast 43 and the elevating table 44 together with the rotary table 42 and determine the direction that the transporter 45 faces (that is, the direction that the transporter 45 can access). For example, as illustrated in FIGS. 1 and 2, when load-scooping of the FOUP 90 placed on the shelf 31 of the storage portion 3B is performed or when unloading of the FOUP 90 to the shelf 31 of the storage portion 3B is performed, the conveyor 4 rotates the rotary table 42 by the rotation control of the rotary table 42 such that the transporter 45 faces the storage portion 3B.

The transporter 45 is, for example, a telescopic robot hand and is provided with the fork 45a at the distal end portion thereof. The fork 45a is capable of scooping up the FOUP 90 placed on the shelf 31 from below and supporting it. For example, on the upper surface of the fork 45a, a protrusion (not depicted) protruding upward is provided and, on the bottom surface of the FOUP 90, a hole (not depicted) into which the protrusion is able to be inserted is provided. That is, by inserting the protrusion on the upper surface of the fork 45a into the hole on the bottom surface of the FOUP 90, the FOUP 90 is positioned at a certain position so as not to slip off from the fork 45a.

The conveyor 4 horizontally swivels the FOUP 90 received from the shelf 31 of one of the storage portions (for example, the storage portion 3A) by 180 degrees and delivers it to the shelf 31 of the other of the storage portions (for example, the storage portion 3B), by the above-described structure. In the following description, one example of transfer operation of the conveyor 4 in which the conveyor 4 delivers the FOUP 90 received from the shelf 31 of the storage portion 3B to the shelf 31 of the storage portion 3A will be explained.

First, by the traveling control of the dolly 41, the elevating control of the elevating table 44, and the rotation control of the rotary table 42, the conveyor 4 moves the transporter 45 to a load-scooping position corresponding to the shelf 31 of the storage portion 3B on which the FOUP 90 that is an object of load-scooping is placed. Then, the conveyor 4 extends the transporter 45 and causes the fork 45a enter below the FOUP 90 to be scooped. Then, the conveyor 4 raises the elevating table 44 such that the fork 45a goes through between the first shelf member 31a and the second shelf member 31b and scoops up the FOUP 90 to be scooped. Thereafter, the conveyor 4 takes in the FOUP 90 by contracting the transporter 45.

Subsequently, the conveyor 4 horizontally swivels the rotary table 42 by 180 degrees so that the transporter 45 faces the storage portion 3A. Accordingly, the FOUP 90 on the fork 45a is horizontally rotated by 180 degrees. That is, the FOUP 90 for which the front surface faced the left-hand direction in a state before being scooped up by the fork 45a (in a state of being placed on the shelf 31 of the storage portion 3B) is changed into a state in which the front surface faces the right-hand direction. Then, by the traveling control of the dolly 41 and the elevating control of the elevating table 44, the conveyor 4 moves the transporter 45 to an unloading position corresponding to the shelf 31 of the storage portion 3A that is a transfer destination of the FOUP 90. Then, the conveyor 4 extends the transporter 45 and causes the FOUP 90 on the fork 45a to enter above the shelf 31 of the transfer destination. Then, the conveyor 4 lowers the elevating table 44 such that the fork 45a travels through an area between the first shelf member 31a and the second shelf member 31b of the relevant shelf 31. Accordingly, the FOUP 90 is handed over to the shelf 31 of the transfer destination from the fork 45a.

When the conveyor 4 transfers the FOUP 90 from one shelf 31 to another shelf 31 within the same storage portion (the storage portion 3A or the storage portion 3B), the direction of the FOUP is not changed before and after the transfer because the horizontal swiveling by 180 degrees is not performed by the rotary table 42.

According to the above-described rotary conveyor 4, the thickness of the fork 45a is able to be relatively small and, as a result, the interval between the FOUPs 90 placed on the shelves 31 adjacent in the up-and-down direction is able to be relatively small. That is, the interval between the shelves 31 adjacent in the up-and-down direction is able to be made relatively small. Accordingly, the storage density of the FOUPs 90 in the height direction of the respective storage portions 3A and 3B is able to be increased. As a result, it is possible to downsize the storage apparatus 1 by shortening the total length in the height direction of the storage apparatus 1.

As illustrated in FIGS. 3 and 4, in a conveyance system 100 including the storage apparatus 1 and the overhead carrier 10, as one example, a track 50 for the overhead carrier is laid along the front-and-rear direction so as to pass above the leftmost row out of the rows of shelves 31 (for example, five rows, in the present preferred embodiment) juxtaposed in the left-and-right direction in the respective storage portions 3A and 3B. The track is laid near the ceiling of the semiconductor manufacturing plant in which the storage apparatus 1 is installed, for example. The overhead carrier 10 is, for example, an overhead hoist transfer (OHT) and travels in one direction (for example, a direction to the rear side from the front side, in the present preferred embodiment) along the track 50 in a state of being suspended from the track 50. That is, in the present preferred embodiment, the storage portion 3A is located on the upstream side in the traveling direction of the overhead carrier 10, and the storage portion 3B is located on the downstream side in the traveling direction of the overhead carrier 10.

The overhead carrier 10 is capable of accessing at least one of the storage portions (both storage portions 3A and 3B, as one example in the present preferred embodiment) of the pair of storage portions 3A and 3B (details will be described later). In addition, the overhead carrier 10 conveys the FOUP 90 along the front-and-rear direction (first direction), in a state in which the front surface of the FOUP 90 faces the left-and-right direction (second direction). In the present preferred embodiment, as one example, the overhead carrier 10 conveys the FOUP 90 along the direction to the rear side from the front side, in a state in which the front surface of the FOUP 90 faces the right-hand side.

The overhead carrier 10 includes a gripper 11 capable of grasping the flange 93 of the FOUP 90, an elevator 13 capable of raising and lowering the gripper 11 by feeding and winding a belt 12 to which the gripper 11 is connected, and a horizontal conveyor 14 capable of horizontally moving the elevator 13 in the direction (“left-and-right direction”, in the present preferred embodiment) orthogonal to the traveling direction (“front-and-rear direction”, in the present preferred embodiment) of the overhead carrier 10.

As illustrated in FIGS. 1 and 3, on the uppermost stage of the leftmost row (the stage that is one stage lower than the uppermost stages of the other rows) of the storage portion 3A, the port 32A is provided with an upper side that is open so that the overhead carrier 10 can have access. Specifically, the overhead carrier 10 is able to perform the transfer (unloading or load-scooping) of the FOUP 90 with the port 32A, by stopping above the port 32A and raising and lowering the gripper 11 by the elevator 13. In the present preferred embodiment, as one example, the port 32A includes the first shelf member 31a and the second shelf member 31b as with the other shelves 31 of the storage portion 3A.

As illustrated in FIGS. 1 and 4, on the uppermost stage of the leftmost row (the stage that is one stage lower than the uppermost stages of the other rows) of the storage portion 3B, the port 32B is provided with an upper side that is open so that the overhead carrier 10 can have access. Specifically, the overhead carrier 10 is able to perform the transfer (unloading or load-scooping) of the FOUP 90 with the port 32B, by stopping above the port 32B and raising and lowering the gripper 11 by the elevator 13. The port 32B includes a swivel that horizontally swivels the FOUP 90 placed on the port 32B by 180 degrees.

In the present preferred embodiment, as one example, the port 32B includes a turntable (swivel) 33 that is capable of horizontally swiveling by 180 degrees and a pair of supports 34 and 34 that are mounted on the turntable 33. The supports 34 and are rectangular or substantially rectangular parallelepiped members provided apart at a certain interval from each other. The supports 34 and 34 extend in the front-and-rear direction, in a normal state (a state in which the transfer of the FOUP 90 is possible). Accordingly, a portion of the front side and a portion of the rear side of the bottom surface of the FOUP 90 are supported by the supports 34 and 34. The interval between the supports 34 and 34 is set to a size that allows the fork 45a of the conveyor 4 to enter and to perform the transfer (load-scooping or unloading) of the FOUP 90. The turntable 33 swivels in a state in which the FOUP 90 is placed on the supports 34 and 34 to rotate the direction of the FOUP 90 by 180 degrees.

Since the turntable 33 is provided on the port 32B, it is possible to carry the FOUP 90 that is received in the port 32A from the port 32B or to carry the FOUP 90 that is received in the port 32B from the port 32A. The following describes this specifically. In the present preferred embodiment, as one example, it is assumed that the overhead carrier 10 conveys the FOUP 90 such that the front surface of the FOUP 90 faces the right-hand side with respect to the traveling direction (direction toward the rear side from the front side).

First, a case of carrying the FOUP 90 received in the port 32A from the port 32B will be described. In this case, as the FOUP 90 is handed over to the port 32A from the overhead carrier 10 stopped above the port 32A, incoming of the FOUP 90 in the port 32A is performed. Immediately after the incoming, the FOUP 90 placed on the port 32A is in a state in which the front surface of the FOUP 90 faces the right-hand direction (see FIGS. 1 and 3).

The FOUP 90 received in the port 32A turns into a state in which the front surface of the FOUP 90 faces the left-hand direction (see the FOUPs 90 in the second to fourth rows from the left of the storage portion 3B in FIG. 1) by the horizontal swiveling (rotation operation of the rotary table 42) of the conveyor 4, in the course of the transfer to the storage portion 3B by the conveyor 4. That is, when the FOUP 90 is ultimately transferred to the port 32B for outgoing, the FOUP 90 received in the port 32A is turned into a state in which the FOUP 90 faces the side opposite to the direction for which the overhead carrier 10 is capable of conveying (in a state in which the front surface of the FOUP 90 faces the left-hand direction). Thus, the turntable horizontally swivels by 180 degrees when the FOUP 90 is transferred to the port 32B by the conveyor 4. Accordingly, the direction of the FOUP 90 on the port 32B can be made coincident with the direction for which the overhead carrier 10 is capable of conveying (that is, a state in which the front surface of the FOUP faces the right-hand direction) (see FIGS. 1 and 4). As a result, the overhead carrier 10 is able to carry the FOUP 90 placed on the port 32B.

Next, a case of carrying the FOUP 90 received in the port 32B from the port 32A will be described. In this case, as the FOUP 90 is handed over to the port 32B from the overhead carrier 10 stopped above the port 32B, incoming of the FOUP 90 in the port 32B is performed. Immediately after the incoming, the FOUP 90 placed on the port 32B is in a state in which the front surface of the FOUP 90 faces the right-hand direction (see FIGS. 1 and 4).

If the FOUP 90 received in the port 32B is not made to swivel horizontally by 180 degrees, the FOUP 90 turns into a state in which the front surface of the FOUP 90 faces the left-hand direction by the horizontal swiveling (rotation operation of the rotary table 42) of the conveyor 4, in the course of the transfer to the storage portion 3A by the conveyor 4. That is, when the FOUP 90 is ultimately transferred to the port 32A for outgoing, the FOUP 90 received in the port 32B is turned into a state in which the FOUP 90 faces the side opposite to the direction for which the overhead carrier 10 is capable of conveying (in a state in which the front surface of the FOUP 90 faces the left-hand direction).

Thus, the turntable 33 horizontally swivels the FOUP 90 received in the port 32B by 180 degrees. Accordingly, the FOUP 90 is turned into a state in which the front surface of the FOUP 90 faces the left-hand direction. As a result, the FOUP 90 turns into a state in which the front surface of the FOUP 90 faces the right-hand direction, in the course of the transfer to the storage portion 3A by the conveyor 4. That is, when the FOUP 90 is ultimately transferred to the port 32A for outgoing, the FOUP 90 received in the port 32B faces the direction for which the overhead carrier 10 is capable of conveying. As a result, the overhead carrier 10 is able to carry the FOUP 90 placed on the port 32A.

As in the foregoing, by the simple configuration in which the port 32B of one of the storage portions (the storage portion 3B, as one example in the present preferred embodiment) includes the turntable 33, the directions of the FOUPs 90 placed on the respective ports 32A and 32B of the storage portions 3A and 3B (that is, the direction of the FOUP 90 immediately after the incoming and the direction of the FOUP 90 immediately before the outgoing) is able to be made coincident with the direction for which the overhead carrier 10 is capable of conveying. As a result, the overhead carrier 10 is able to use any of the ports 32A and 32B of the storage portions 3A and 3B for incoming or outgoing. Accordingly, it is possible to improve the efficiency of the incoming-and-outgoing operations of the FOUPs 90 by the overhead carrier 10.

One port out of the ports 32A and 32B may be set as a port for incoming and the other port may be set as a port for outgoing. According to this structure, the storage portions 3A and 3B are able to be divided into a storage portion exclusively for incoming and a storage portion exclusively for outgoing. As a result, it is possible to smoothly perform the incoming and outgoing of the FOUP 90 by the overhead carrier 10 and is possible to significantly reduce or prevent the occurrence of the congestion of the overhead carrier 10. For example, the port 32A of the storage portion of the upstream side in the traveling direction of the overhead carrier 10 (the storage portion 3A in the present preferred embodiment) may be set as the port for incoming and the port 32B of the storage portion of the downstream side in the traveling direction of the overhead carrier 10 (the storage portion 3B in the present preferred embodiment) may be set as the port for outgoing. In this case, a single overhead carrier 10 is able to perform both incoming and outgoing of the FOUPs 90 by a series of traveling operations. Specifically, a single overhead carrier 10 is able to, after unloading the FOUP 90 (incoming) to the port 32A of the upstream side, perform load-scooping of the FOUP 90 (outgoing) from the port 32B of the downstream side. As a result, it is possible to improve the operational efficiency of the overhead carrier 10.

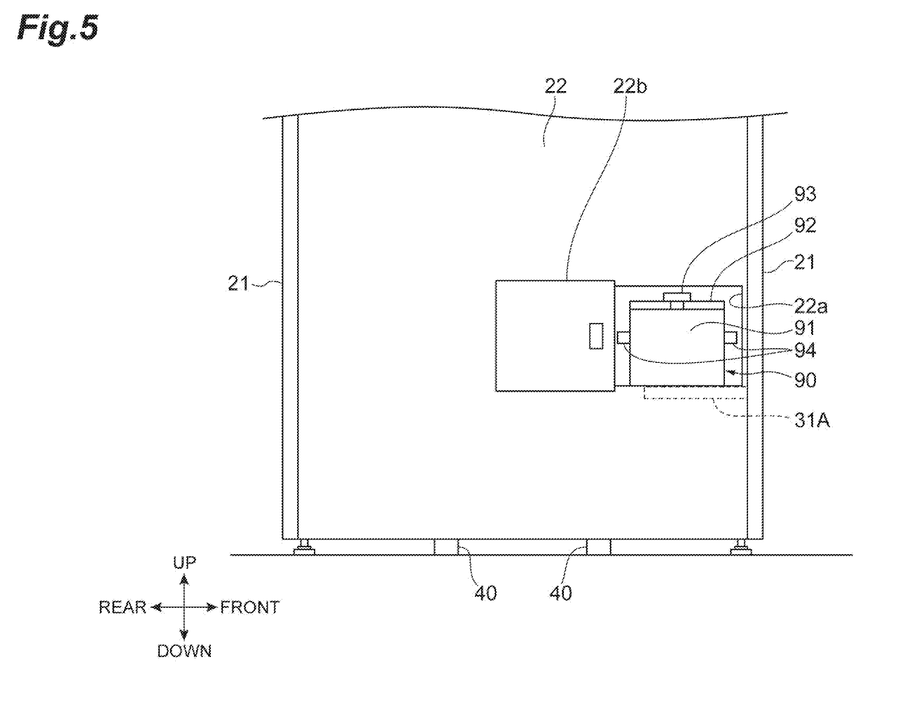

As illustrated in FIG. 5, in the present preferred embodiment, as one example, an opening 22a is provided at a portion of a sidewall portion 22 on the left-hand side adjacent to a space on a specific shelf 31A that is located at a certain height position of the leftmost row of the storage portion 3A, and a shutter 22b that covers the opening 22a is provided. The FOUP 90 placed on the shelf 31A is in a state in which the front surface faces the right-hand direction. Accordingly, the worker is able to access the FOUP 90 placed on the shelf 31A, by opening the shutter 22b (by sliding it to the rear direction, as one example in the present preferred embodiment). The worker can easily take out the FOUP 90, by holding the FOUP 90 from the rear side and gripping the pair of handles 94 with both hands. Furthermore, when storing the FOUP 90 in the shelf 31A, the worker is able to easily store the FOUP 90 in the shelf 31A by the reverse operation to the operation in taking out the FOUP 90. As just described, in the storage apparatus 1, since the FOUP 90 is placed on the shelf 31 such that the front surface faces the left-and-right direction, it is possible to construct a manual port that allows the worker to put in and out the FOUP 90 easily by the simple configuration in which the opening 22a is provided on the sidewall portion 22. Specifically, without providing a mechanism that changes the direction of the FOUP 90 within the storage apparatus 1, it is possible to construct the manual port that allows the FOUP 90 to be put in and out from the gable side of the storage apparatus 1.

In the above-described storage apparatus 1, in each of the storage portions 3A and 3B, the FOUPs 90 are placed such that the front surface of the FOUP 90 faces the array direction of the shelves 31 (that is, the longitudinal direction of the storage portions 3A and 3B). The front-to-rear width w1 of the FOUP 90 is narrower than the right-to-left width w2 of the FOUP 90. Thus, according to the storage apparatus 1, the storage density of the FOUPs 90 in the longitudinal direction of the respective storage portions 3A and 3B is increased as compared with the configuration in which the FOUPs 90 are placed on the shelves 31 such that the side surface of the FOUP 90 faces the array direction of the shelves 31. As a result, it is possible to downsize the storage apparatus 1 by shortening the total length in the longitudinal direction of the storage apparatus 1.

The conveyor 4 horizontally swivels by 180 degrees the FOUP 90 that is received from the shelf 31 of one storage portion of the storage portions 3A and 3B, and hands it over to the shelf 31 of the other storage portion. As in the foregoing, by making the conveyor 4 have such a structure, the intervals between the FOUPs 90 placed on the shelves 31 adjacent in the up-and-down direction are able to be made relatively small. Accordingly, the storage density of the FOUPs 90 in the height direction of the respective storage portions 3A and 3B is increased. As a result, it is possible to downsize the storage apparatus 1 by shortening the total length in the height direction of the storage apparatus 1.

Each of the storage portions 3A and 3B includes the port 32A or 32B that the overhead carrier 10 that travels along the direction toward the rear side from the front side (first direction) and conveys the FOUPs 90 is able to have access. The port of one storage portion (the port 32B of the storage portion 3B, as one example in the present preferred embodiment) of the storage portions 3A and 3B includes the turntable 33 that horizontally swivels the FOUP 90 placed on the port 32B by 180 degrees. Since the conveyor 4 horizontally swivels the FOUP 90 by 180 degrees in transferring the FOUP 90 from the shelf 31 of the storage portion 3A to the shelf 31 of the storage portion 3B, the direction of the FOUP 90 placed on the shelf 31 of the storage portion 3A and the direction of the FOUP 90 placed on the shelf 31 of the storage portion 3B are opposite to each other. The same applies to a case in which the conveyor 4 transfers the FOUP 90 from the shelf 31 of the storage portion 3B to the shelf 31 of the storage portion 3A. Meanwhile, the direction of the FOUP 90 for which the overhead carrier 10 is capable of conveying (the direction of the FOUP 90 with respect to the traveling direction of the overhead carrier 10) is predetermined. According to the above-described configuration, by the simple structure in which the turntable 33 is provided on the port 32B of the storage portion 3B, the directions of the FOUPs 90 placed on the respective ports 32A and 32B of the storage portions 3A and 3B (that is, the direction of the FOUP 90 immediately after the incoming and the direction of the FOUP 90 immediately before the outgoing) are able to be made coincident with the direction for which the overhead carrier 10 is capable of conveying. As a result, the overhead carrier 10 is able to use any of the ports 32A and 32B of the storage portions 3A and 3B for incoming or outgoing. Accordingly, it is possible to improve the efficiency of the incoming-and-outgoing operations of the FOUPs 90 by the overhead carrier 10.

The conveyance system 100 includes the storage apparatus 1, and the overhead carrier 10 that is capable of accessing at least one of the storage portions (both storage portions 3A and 3B, as one example in the present preferred embodiment) of the pair of storage portions 3A and 3B and conveys along the front-and-rear direction the FOUP 90 in a state in which the front surface of the FOUP 90 faces the left-and-right direction. In the conveyance system 100, by the above-described reasons, it is possible to downsize the storage apparatus 1 by shortening the respective total lengths in the longitudinal direction and the up-and-down direction of the storage apparatus 1. In the conveyance system 100, the FOUP 90 that is conveyed by the overhead carrier 10, and the FOUPs 90 that are placed on the storage portions 3A and 3B are all in a state in which the front surface of the FOUP 90 faces the left-and-right direction. Accordingly, there is no need to have a mechanism or the like that is needed when the traveling direction of the overhead carrier 10 and the direction of the storage portions 3A and 3B facing each other are orthogonal (for example, a mechanism that horizontally swivels the FOUP 90 placed on the storage portions 3A and 3B by 90 degrees). Thus, according to the conveyance system 100 in which the storage apparatus 1 and the overhead carrier 10 are arranged as in the foregoing, it is possible to simplify the structure of the storage apparatus 1.

### Second Preferred Embodiment

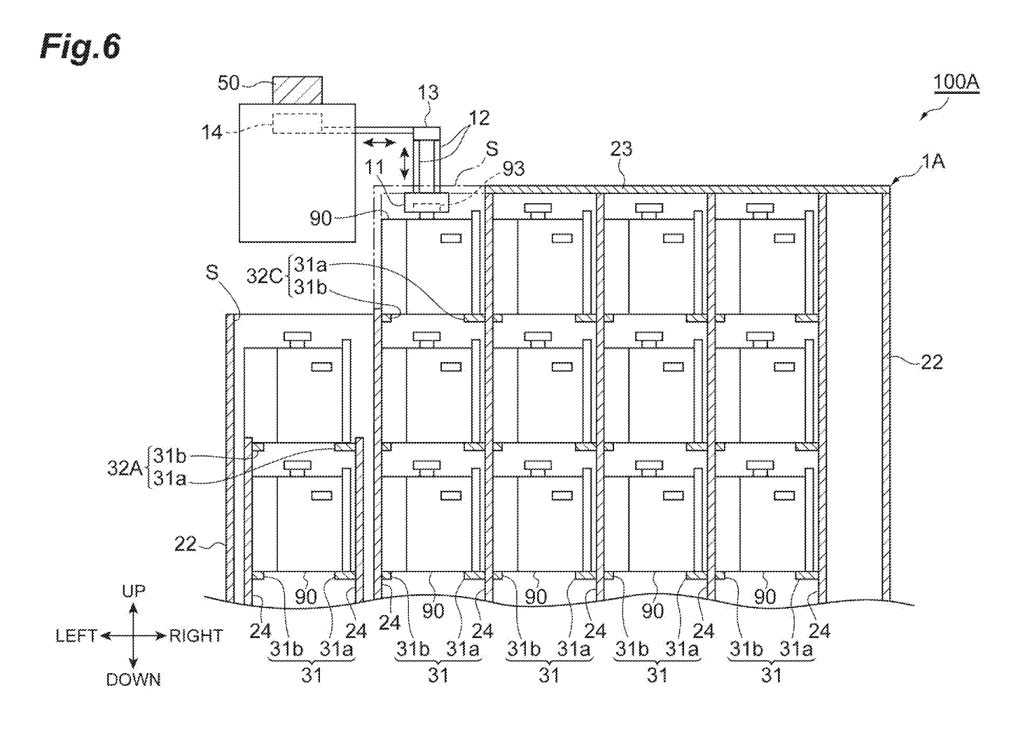

With reference to FIG. 6, a storage apparatus 1A according to a second preferred embodiment of the present invention will be described. The storage apparatus 1A is mainly different from the storage apparatus 1 in that it is structured so that the uppermost shelf of the second row from the left of the storage portion 3A is available as a port 32C for incoming and outgoing of the FOUP 90. In the storage apparatus 1A, the storage portion 3A includes two ports 32A and 32C. The port 32A and the port 32C are different from each other in both height position (positions in the up-and-down direction) and the horizontal position (positions in the left-and-right direction). Specifically, the port 32C is located at the stage one stage higher than the port 32A and in the row on the right-hand side thereof.

As one example, in the storage apparatus 1A, the housing 2 is structured such that the upper side and the left-hand side of the FOUP 90 placed on the uppermost shelf in the second row from the left of the storage portion 3A (the port 32C) are opened. Specifically, a portion of the top plate portion 23 and a portion of the support post 24 are cut out. Accordingly, the overhead carrier 10 that stopped above the port 32A is able to access the port 32C by what is called lateral transfer. Specifically, as illustrated in FIG. 6, the overhead carrier 10 that stopped above the port 32A is able to perform the transfer of the FOUP 90 with the port 32C, by moving the elevator 13 in the right-hand direction by the horizontal conveyor 14 and raising and lowering the gripper 11 by the elevator 13.

As just described, the storage portion 3A includes the port (first port) 32A at which incoming or outgoing of the FOUP 90 is performed as the overhead carrier 10 at the position above the port 32A (a certain stop position) moves the FOUP 90 in the up-and-down direction. Furthermore, the storage portion 3A includes the port (second port) 32C at which incoming or outgoing of the FOUP 90 is performed as the overhead carrier 10 at the position above the port 32A moves the FOUP 90 in the left-and-right direction and the up-and-down direction. According to this configuration, it is possible to perform the incoming-and-outgoing operations (that is, accessing the port 32A and the port 32C) by the overhead carrier 10 stopped at the certain position as a series of transfer operations. For example, the overhead carrier 10 is able to, after depositing the FOUP 90 at one of the port 32A and the port 32C, carry the FOUP 90 from the other of the port 32A and the port 32C. As a result, it is possible to smoothly perform the incoming and outgoing of the FOUP 90 by the overhead carrier 10 and is possible to significantly reduce or prevent the occurrence of the congestion of the overhead carrier 10. A conveyance system 100A including the storage apparatus 1A and the overhead carrier 10 also achieves the same advantageous effects as those of the above-described conveyance system 100.

Preferred embodiments of the present disclosure have been described. The disclosure and present invention, however, are not limited to the above-described preferred embodiments. For example, conceivable is a case in which both incoming and outgoing of the FOUP 90 are performed at one or more ports provided on one of the storage portions, and in which incoming and outgoing of the FOUP 90 are not performed on the other of the storage portions (for example, a case in which, as in the second preferred embodiment, two ports 32A and 32C are provided on one of the storage portions (the storage portion 3A in the above example)). In such a case, since a situation in which the FOUP 90 received in the port of one of the storage portions is carried from the port of the other of the storage portions never occurs, there may be no need to provide a turntable (swivel) to one port as in the first preferred embodiment.

A construction that is a combination of the configurations of the above-described first preferred embodiment and the second preferred embodiment may be used. In this case, two ports 32A and 32C are provided on one of the storage portions (the storage portion 3A in the above-described example) and one port 32B is provided on the other of the storage portions (the storage portion 3B in the above-described example).

A container that a conveyance system according to a preferred embodiment of the present invention conveys is not limited to the FOUP 90 in which a plurality of semiconductor wafers are accommodated, and it may be other containers in which glass wafers, reticles, or the like are accommodated. Conveyance systems according to preferred embodiments of the present invention are not limited to a semiconductor manufacturing plant and are also applicable to other facilities.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1-6. (canceled)

7. A storage apparatus comprising:
a pair of storage portions including a plurality of shelves on which a container of a front-to-rear width narrower than a right-to-left width is to be placed, the storage portions facing each other in a first direction; and
a conveyor provided between the pair of storage portions to transfer the container between the shelves of the pair of storage portions; wherein
in each of the pair of storage portions, the plurality of shelves that are located at an identical height position are arrayed in a second direction orthogonal to the first direction; and
the conveyor places the container on each of the plurality of shelves in a state in which a front surface of the container faces the second direction.

8. The storage apparatus according to claim 7, wherein the conveyor horizontally swivels the container received from the shelf of one storage portion of the pair of storage portions by 180 degrees and hands the container over to the shelf of the other storage portion of the pair of storage portions.

9. The storage apparatus according to claim 8, wherein
each of the pair of storage portions includes a port that is able to be accessed by an overhead carrier that conveys the container along the first direction; and
the port of one of the storage portions includes a swivel that horizontally swivels the container placed on the port by 180 degrees.

10. The storage apparatus according to claim 9, wherein
the port of one storage portion of the pair of storage portions is a port for incoming; and
the port of the other storage portion of the pair of storage portions is a port for outgoing.

11. The storage apparatus according to claim 7, wherein
at least one of the storage portions of the pair of storage portions includes:
a first port at which incoming or outgoing of the container is performed by an overhead carrier that conveys the container moving the container in an up-and-down direction at a certain stop position; and
a second port at which incoming or outgoing of the container is performed by the overhead carrier moving the container in a horizontal direction and the up-and-down direction at the certain stop position.

12. A conveyance system comprising:
the storage apparatus according to claim 7; and
an overhead carrier that is able to access at least one storage portion of the pair of storage portions and that conveys the container along the first direction in a state in which the front surface of the container faces the second direction.
